(19) United States
(12) Patent Application Publication
(10) Pub. No.: US 2025/0197998 A1
(43) Pub. Date: Jun. 19, 2025

(54) Pipe Heating System, Substrate Processing Apparatus and Method of Manufacturing Semiconductor Device

(71) Applicant: Kokusai Electric Corporation, Tokyo (JP)

(72) Inventors: Hideto YAMAGUCHI, Toyama (JP); Kaoru YAMAMOTO, Toyama (JP)

(21) Appl. No.: 19/071,331

(22) Filed: Mar. 5, 2025

Related U.S. Application Data
(63) Continuation of application No. PCT/JP2022/035794, filed on Sep. 26, 2022.

(51) Int. Cl. C23C 16/455; C23C 16/52

(52) U.S. Cl. CPC C23C 16/45561; C23C 16/52

(57) ABSTRACT

It is possible to uniformly heat a piping structure. There is provided a technique that includes: a latent heat accumulator arranged outside a pipe through which a fluid flows; a heater arranged outside the latent heat accumulator; a power supply configured to supply an electric power to the heater; and a controller configured to be capable of controlling the power supply such that the heater heats the pipe to maintain a temperature of the latent heat accumulator at a phase change temperature.

### CROSS REFERENCE TO RELATED APPLICATIONS

This application is a bypass continuation application of PCT International Application No. PCT/JP2022/035794, filed on Sep. 26, 2022, in the WIPO, the entire contents of which are hereby incorporated by reference.

### TECHNICAL FIELD

The present disclosure relates to a pipe heating system, a substrate processing apparatus and a method of manufacturing a semiconductor device.

### BACKGROUND

According to some related arts, as a part of a manufacturing process of a semiconductor device, a process of forming a film on a substrate may be performed. According to some related arts, a process gas (which is in a gaseous state) is introduced into a process chamber by heating a piping structure related thereto such that the process gas flows over a wafer (hereinafter, also referred to as a “substrate”). However, it may be difficult to uniformly heat the piping structure. In addition, a cold spot may occur.

### SUMMARY

According to the present disclosure, there is provided a technique capable of uniformly heating a piping structure.

According to an embodiment of the present disclosure, there is provided a technique that includes: a latent heat accumulator arranged outside a pipe through which a fluid flows; a heater arranged outside the latent heat accumulator; a power supply configured to supply an electric power to the heater; and a controller configured to be capable of controlling the power supply such that the heater heats the pipe to maintain a temperature of the latent heat accumulator at a phase change temperature.

### BRIEF DESCRIPTION OF THE DRAWINGS

FIG. 1 is a diagram schematically illustrating a vertical cross-section of a vertical type process furnace of a substrate processing apparatus according to a first embodiment of the present disclosure.

FIG. 2 is a diagram schematically illustrating a functional configuration of a controller of the substrate processing apparatus according to the first embodiment of the present disclosure.

FIG. 3A is a diagram schematically illustrating a horizontal cross-section for explaining a configuration of a pipe heating system according to the first embodiment of the present disclosure, and FIG. 3B is a diagram schematically illustrating a vertical cross-section of the pipe heating system shown in FIG. 3A.

FIG. 4A is a diagram schematically illustrating another horizontal cross-section for explaining the configuration of the pipe heating system according to the first embodiment of the present disclosure, and FIG. 4B is a diagram schematically illustrating a vertical cross-section of the pipe heating system shown in FIG. 4A.

FIG. 5 is a block diagram schematically illustrating the pipe heating system according to the first embodiment of the present disclosure.

FIG. 6A is a diagram schematically illustrating a relationship among a power supply to the pipe heating system according to the first embodiment of the present disclosure, an amount of a heat accumulated in a latent heat accumulator and a temperature (inner temperature) of a piping structure, and FIG. 6B is a diagram schematically illustrating a timing of the power supply to the pipe heating system according to the first embodiment of the present disclosure.

FIG. 7 is a diagram schematically illustrating a timing of a power supply to a pipe heating system according to a second embodiment of the present disclosure.

FIG. 8A is a diagram schematically illustrating a horizontal cross-section for explaining a configuration of a pipe heating system according to a third embodiment of the present disclosure, and FIG. 8B is a diagram schematically illustrating a vertical cross-section of the pipe heating system shown in FIG. 8A.

### DETAILED DESCRIPTION

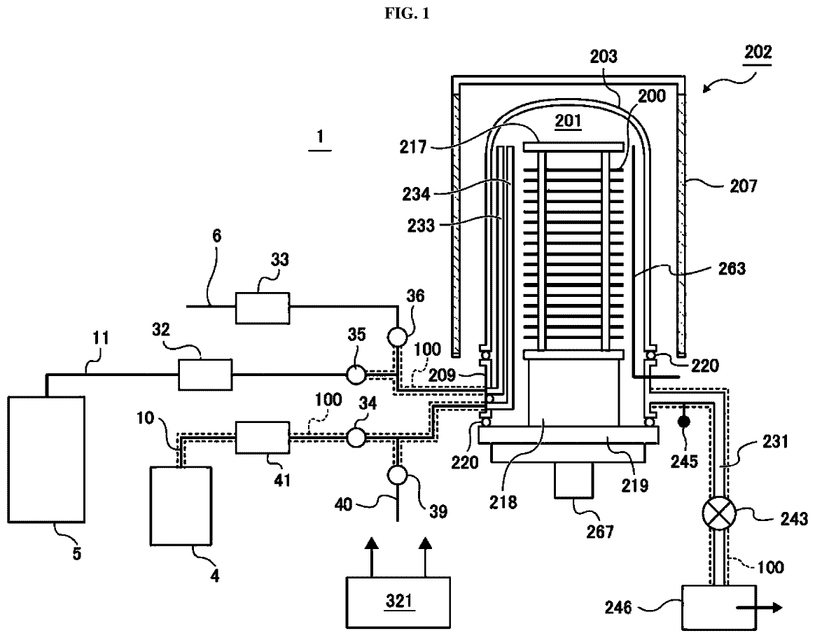

Hereinafter, one or more embodiments (also simply referred to as “embodiments”) according to the technique of the present disclosure will be described with reference to FIGS. 1 to 8B. In addition, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. Hereinafter, first, a first embodiment according to the technique of the present disclosure will be described.

### (1) Configuration of Substrate Processing Apparatus

A substrate processing apparatus 1 according to the first embodiment of the present disclosure will be described with reference to FIG. 1. FIG. 1 is a diagram schematically illustrating a case in which a plurality of pipe heaters 100 (which are heating structures) are provided at a portion corresponding to a downstream side of a valve 36 of a supply pipe 6, a portion corresponding to a supply pipe 10, a portion corresponding to a downstream side of a valve 35 of a supply pipe 11, a portion corresponding to a downstream side of a valve 39 of a supply pipe 40 and a portion corresponding to an exhaust pipe 231. Hereinafter, each of the pipe heaters 100 may also be referred to as a “pipe heater 100”. Each of the supply pipes 6, 10, 11 and 40 and the exhaust pipe 231 is configured as a pipe (also referred to as a “piping structure”) through which a fluid can flow.

### Process Furnace

As shown in FIG. 1, inside a heater 207 serving as a heating structure, a reaction tube 203 is provided. The reaction tube 203 serves as a process vessel in which a wafer 200 serving as a substrate is processed. A lower end opening of the reaction tube 203 is airtightly closed by a seal cap 219 serving as a lid via an O-ring 220 serving as a seal (airtight structure). A process furnace 202 is constituted by at least the heater 207, the reaction tube 203, a manifold 209 serving as a furnace opening and the seal cap 219. In addition, a process chamber 201 is constituted by at least the reaction tube 203, the manifold 209 and the seal cap 219. A boat 217 (which is a substrate holding structure or a substrate retainer) is provided on the seal cap 219 via a quartz cap 218, and is inserted into the process chamber 201. A plurality of wafers including the wafer 200 to be batch-processed are horizontally oriented to be stacked in a multistage manner on the boat 217. Hereinafter, the plurality of wafers including the wafer 200 may also be simply referred to as “wafers 200”. The heater 207 is configured to heat the wafers 200 inserted into the process chamber 201 to a predetermined temperature.

A gas supply source 4 configured to supply a first process gas serving as one of process gases, a flow rate controller (mass flow controller, MFC) 41 configured to control a flow rate of the first process gas, a valve 34 serving as an opening/closing valve and a nozzle 234 are connected to the supply pipe 10 in this order from an upstream side to a downstream side of the supply pipe 10 in a gas flow direction. The first process gas is supplied into the process chamber 201 through the nozzle 234. For example, a first process gas supplier (which is a first process gas supply system or a first process gas supply structure) is constituted by the supply pipe 10, the MFC 41, the valve 34 and the nozzle 234. The first process gas supplier may further include the gas supply source 4. For example, the first process gas supplier may also be referred to as a gas supplier (which is a gas supply system or a gas supply structure).

A gas supply source 5 configured to supply a second process gas serving as one of the process gases, a flow rate controller (mass flow controller, MFC) 32 configured to control a flow rate of the second process gas, the valve 35 and a nozzle 233 are connected to the supply pipe 11 in this order from an upstream side to a downstream side of the supply pipe 11 in the gas flow direction. The second process gas is supplied into the process chamber 201 through the nozzle 233. For example, a second process gas supplier (which is a second process gas supply system or a second process gas supply structure) is constituted by the supply pipe 11, the MFC 32, the valve 35 and the nozzle 233. The second process gas supplier may further include the gas supply source 5. For example, the second process gas supplier may also be referred to as a gas supplier (which is a gas supply system or a gas supply structure).

The supply pipe 40 through which an inert gas is supplied is connected to a downstream side of the valve 34 of the supply pipe 10. The valve 39 is provided at the supply pipe 40. In addition, the supply pipe 6 through which the inert gas is supplied is connected to the downstream side of the valve 35 of the supply pipe 11. An MFC 33 and the valve 36 are provided at the supply pipe 6.

The exhaust pipe (which is an exhaust pipe through which a gas such as the first process gas is exhausted) 231 is connected to the process chamber 201. A pressure sensor 245, an APC (Automatic Pressure Controller) valve 243 and a vacuum pump 246 are connected to the exhaust pipe 231 in this order from an upstream side to a downstream side of the exhaust pipe 231 in the gas flow direction. For example, a gas exhauster (which is a gas exhaust system or a gas exhaust structure) is constituted by the exhaust pipe 231, the pressure sensor 245 and the APC valve 243. The gas exhauster may further include the vacuum pump 246. The gas exhauster may also be referred to as an “exhauster” which is an exhaust system or an exhaust structure.

The nozzle 234 is installed from a lower portion to an upper portion of the reaction tube 203 along a stacking direction of the wafers 200. The nozzle 234 is provided with a plurality of gas supply holes (not shown) through which the gas is supplied. Each of the gas supply holes is opened at a midpoint between adjacent wafers among the wafers 200 such that the gas is supplied to a surface of each of the wafers 200. Similarly, the nozzle 233 is installed at a position about 120° around an inner circumference of the reaction tube 203 from a position of the nozzle 234 to extend along the stacking direction of the wafers 200. The nozzle 233 is also provided with a plurality of gas supply holes (not shown). The nozzle 234 is configured such that the first process gas supplied through the supply pipe 10 and the inert gas supplied through the supply pipe 40 are supplied into the process chamber 201. In addition, the nozzle 233 is configured such that the second process gas supplied through the supply pipe 11 and the inert gas supplied through supply pipe 6 are supplied into the process chamber 201. By alternately supplying the process gases (that is, the first process gas and the second process gas) into the process chamber 201 through the nozzle 234 and the nozzle 233, it is possible to form a film on the wafer 200.

The boat 217 is provided in the reaction tube 203. The wafers 200 can be placed in the boat 217 at an equal interval therebetween in a multistage manner. The boat 217 can be transferred (loaded) into and transferred (unloaded) out of the reaction tube 203 by a boat elevator (not shown). In addition, a boat rotator (which is a boat rotating structure capable of rotating the boat 217 to improve a uniformity of a processing) 267 is provided. By rotating the boat rotator 267, the boat 217 supported (held) by the quartz cap 218 is rotated.

### Controller

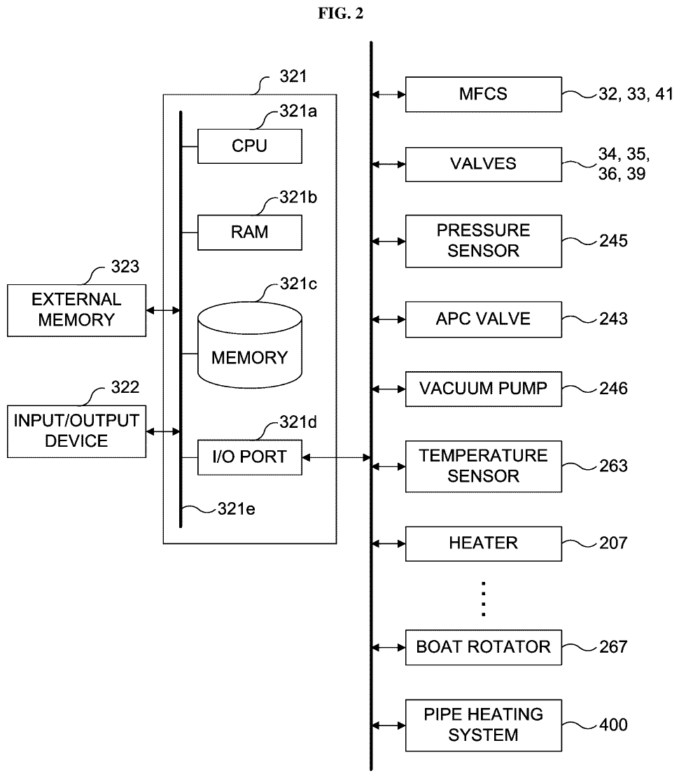

A controller 321 serving as a control structure (control apparatus) will be described with reference to FIG. 2. For example, the controller 321 is constituted by a computer including a CPU (Central Processing Unit) 321a, a RAM (Random Access Memory) 321b, a memory 321c and an I/O port (input/output port) 321d. The RAM 321b, the memory 321c and the I/O port 321d are configured to exchange data with the CPU 321a through an internal bus 321e. For example, an input/output device 322 constituted by a component such as a touch panel is connected to the controller 321.

The memory 321c is configured by a component such as a flash memory and a hard disk drive (HDD). For example, a control program configured to control an operation of the substrate processing apparatus 1 or a process recipe containing information on procedures and conditions of a substrate processing described later is readably stored in the memory 321c. The process recipe is obtained by combining steps (procedures) of the substrate processing described later such that the controller 321 can execute the steps to acquire a predetermined result. For example, the RAM 321b functions as a memory area (work area) where a program or data read by the CPU 321a is temporarily stored.

The I/O port 321d is connected to the components described above such as the MFCs 32, 33 and 41, the valves 34, 35, 36 and 39, the pressure sensor 245, the APC valve 243, the vacuum pump 246, the heater 207, a temperature sensor 263, the boat rotator 267 and a pipe heating system 400 described later.

The CPU 321a is configured to read the control program from the memory 321c and execute the control program. In addition, the CPU 321a is configured to read the process recipe from the memory 321c in accordance with an operation command inputted from the input/output device 322. In accordance with contents of the process recipe, the CPU 321a may be configured to control various operations such as flow rate adjusting operations for various gases by the MFCs 32, 33 and 41, opening and closing operations of the valves 34, 35, 36 and 39, an opening and closing operation of the APC valve 243, a pressure adjusting operation by the APC valve 243 based on the pressure sensor 245, a temperature adjusting operation by the heater 207 based on the temperature sensor 263, a start and stop of the vacuum pump 246, an operation of adjusting a rotation and a rotation speed of the boat 217 by the boat rotator 267 and a temperature adjusting operation by the pipe heater 100 in the pipe heating system 400.

The controller 321 may be embodied by installing the above-mentioned program stored in an external memory 323 into the computer. For example, the external memory 323 may include a semiconductor memory such as a USB memory and a memory card. The memory 321c or the external memory 323 may be embodied by a non-transitory computer readable recording medium. Hereafter, the memory 321c and the external memory 323 may be collectively or individually referred to as a “recording medium”. Thus, in the present specification, the term “recording medium” may refer to the memory 321c alone, may refer to the external memory 323 alone, and may refer to both of the memory 321c and the external memory 323. Instead of the external memory 323, a communication structure such as the Internet and a dedicated line may be used for providing the program to the computer.

### (2) Substrate Processing

Hereinafter, as a part of a manufacturing process of a semiconductor device, an exemplary sequence of the substrate processing (such as a film forming process of forming a film on the substrate (that is, the wafer 200)) will be described. The film forming process is performed using the substrate processing apparatus 1 mentioned above. The present embodiment will be described by way of an example in which the film is formed on the wafer 200 by alternately supplying the first process gas and the second process gas to the wafer 200. In the following description, operations of the components constituting the substrate processing apparatus 1 are controlled by the controller 321.

In the present specification, the terms “substrate” and “wafer” may be used as substantially the same meaning.

### Wafer Charging Step and Boat Loading Step

The wafers 200 are charged (transferred) into the boat 217. After the boat 217 is charged with the wafers 200, the boat 217 is elevated by the boat elevator (not shown) and loaded (transferred) into the process chamber 201. In such a state, the seal cap 219 airtightly closes (seals) a lower end of the reaction tube 203 via the O-ring 220.

### Pressure Adjusting Step and Temperature Adjusting Step

Then, the vacuum pump 246 vacuum-exhausts an atmosphere (inner atmosphere) of the process chamber 201 (that is, a space in which the wafers 200 are present (accommodated)) such that a pressure (inner pressure) of the process chamber 201 reaches and is maintained at a desired pressure (vacuum degree). When the vacuum pump 246 vacuum-exhausts the inner atmosphere of the process chamber 201, the inner pressure of the process chamber 201 is measured by the pressure sensor 245, and the APC valve 243 is feedback-controlled based on pressure information detected by the pressure sensor 245. The vacuum pump 246 is continuously operated until at least a processing of the wafer 200 is completed.

In addition, the heater 207 heats the process chamber 201 such that a temperature of the wafer 200 in the process chamber 201 reaches and is maintained at a desired temperature. When the heater 207 heats the process chamber 201, a state of electric conduction to the heater 207 is feedback-controlled based on temperature information detected by the temperature sensor 263 such that a desired temperature distribution of a temperature (inner temperature) of the process chamber 201 can be obtained. The heater 207 continuously heats the process chamber 201 until at least the processing of the wafer 200 is completed.

In addition, the pipe heating system 400 heats the portion corresponding to the supply pipe 10, the portion corresponding to the downstream side of the valve 35 of the supply pipe 11, the portion corresponding to the downstream side of the valve 39 of the supply pipe 40, the portion corresponding to the downstream side of the valve 36 of the supply pipe 6 and the portion corresponding to the exhaust pipe 231 such that desired temperature distributions of temperatures (inner temperatures) of the portions mentioned above can be obtained. The pipe heating system 400 continuously heats the portions mentioned above until at least the processing of the wafer 200 is completed.

In addition, the rotation of the boat 217 and a rotation of the wafers 200 are started by the boat rotator 267. As the boat rotator 267 rotates the boat 217, the wafers 200 are rotated. The boat rotator 267 continuously rotates the boat 217 and the wafer 200 until at least the processing of the wafer 200 is completed.

### Film Forming Step of Substrate Processing

When the inner temperature of the process chamber 201 is stabilized at a process temperature (which is set in advance), the following two steps, that is, a first step and a second step are sequentially performed. In the present specification, the term “process temperature” may refer to the temperature of the wafer 200 or the inner temperature of the process chamber 201, and the term “process pressure” may refer to the inner pressure of the process chamber 201. In addition, the term “process time” may refer to a time (time duration) of continuously performing a process related thereto. The same also applies to the following descriptions.

### First Step

In the present step, the valve 34 is opened to supply the first process gas into the supply pipe 10 from the gas supply source 4. A flow rate of the first process gas supplied into the supply pipe 10 is adjusted by the MFC 41. The first process gas whose flow rate is adjusted is then supplied into the process chamber 201 through the valve 34 and the nozzle 234, and is exhausted through the exhaust pipe 231. Thereby, the first process gas is supplied to the wafer 200. In the present step, simultaneously with a supply of the first process gas, the valve 39 is opened to supply the inert gas such as nitrogen (N₂) gas into the supply pipe 10 through the supply pipe 40. The inert gas is then supplied into the process chamber 201 together with the first process gas, and is exhausted through the exhaust pipe 231. By supplying the first process gas to the wafer 200, a first layer is formed on an uppermost surface (top surface) of the wafer 200.

After the first layer is formed, the valve 34 is closed to stop the supply of the first process gas. In such a state, with the APC valve 243 open, the vacuum pump 246 vacuum-exhausts the inner atmosphere of the process chamber 201 to discharge (or remove) the first process gas (which remains unreacted or which already contributed to a formation of the first layer) remaining in the process chamber 201 out of the process chamber 201. Further, when the vacuum pump 246 vacuum-exhausts the inner atmosphere of the process chamber 201, by maintaining the valve 39 open, the inert gas is continuously supplied into the process chamber 201. The inert gas serves as a purge gas, which improves an efficiency of removing the gas remaining in the process chamber 201 out of the process chamber 201.

### Second Step

After the first step is completed, the second process gas is supplied to the wafer 200 in the process chamber 201, that is, to the first layer formed on the wafer 200. The second process gas is activated by the heat and supplied to the wafer 200.

In the present step, opening and closing of the valves 35 and 36 can be controlled in the same manners as those of the valves 34 and 39 in the first step. Specifically, the valve 35 is opened to supply the second process gas into the supply pipe 11 from the gas supply source 5. A flow rate of the second process gas supplied into the supply pipe 11 is adjusted by the MFC 32. The second process gas whose flow rate is adjusted is then supplied into the process chamber 201 through the valve 35 and the nozzle 233, and is exhausted through the exhaust pipe 231. Thereby, the second process gas is supplied to the wafer 200. In the present step, simultaneously with a supply of the second process gas, the valve 36 is opened to supply the inert gas into the supply pipe 11 through the supply pipe 6. The inert gas is then supplied into the process chamber 201 together with the second process gas, and is exhausted through the exhaust pipe 231. The second process gas supplied to the wafer 200 reacts with at least a part of the first layer formed on the wafer 200 in the first step. As a result, the first layer is changed (modified) into a second layer.

After the second layer is formed, the valve 35 is closed to stop the supply of the second process gas. Then, in accordance with the same process procedures as in the first step, a substance remaining in the process chamber 201 such as the second process gas (which remains unreacted or which already contributed to a formation of the second layer) and reaction by-products is discharged (removed) out of the process chamber 201. When the vacuum pump 246 vacuum-exhausts the inner atmosphere of the process chamber 201, similar to the first step, the substance such as the second process gas remaining in the process chamber 201 may not be completely discharged (exhausted) out of the process chamber 201.

### Performing Predetermined Number of Times

By performing a cycle (in which the first step and the second step mentioned above are performed non-simultaneously, that is, in a non-synchronized manner) a predetermined number of times (n times), it is possible to form a film with a predetermined thickness on the wafer 200.

### Purge Step and Returning to Atmospheric Pressure Step

After the film forming step of the substrate processing is completed, the valves 36 and 39 are opened to supply the inert gas into the process chamber 201 through the supply pipes 6 and 11 and the supply pipes 40 and 10, and is exhausted through the exhaust pipe 231. The inert gas serves as the purge gas. Thereby, the inner atmosphere of the process chamber 201 is purged with the purge gas. As a result, a substance such as a residual gas remaining in the process chamber 201 and the reaction by-products remaining in the process chamber 201 can be removed from the process chamber 201 (after-purge step). Thereafter, the inner atmosphere of the process chamber 201 is replaced with the inert gas (substitution by inert gas), and the inner pressure of the process chamber 201 is returned to the normal pressure (atmospheric pressure) (returning to atmospheric pressure step).

### Boat Unloading Step and Wafer Discharging Step

Thereafter, the seal cap 219 is lowered by the boat elevator (not shown) and the lower end of the reaction tube 203 is opened. Then, the boat 217 with the wafers 200 (which are processed) supported therein is unloaded (transferred) out of the reaction tube 203 through the lower end of the reaction tube 203. After the boat 217 is unloaded, the wafers 200 (which are processed) are discharged (transferred) from the boat 217.

### (3) Configuration of Pipe Heating system

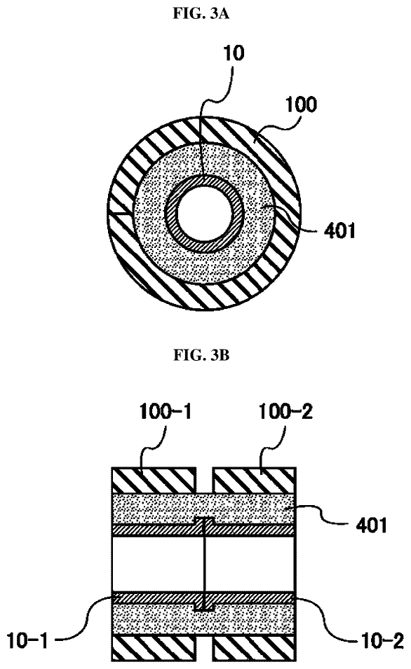

Subsequently, the pipe heating system 400 used in the substrate processing apparatus 1 mentioned above will be described in detail with reference to FIGS. 3A to 6B.

As described above, the pipe heaters 100 are provided at the portion corresponding to the downstream side of the valve 36 of the supply pipe 6, the portion corresponding to the supply pipe 10, the portion corresponding to the downstream side of the valve 35 of the supply pipe 11, the portion corresponding to the downstream side of the valve 39 of the supply pipe 40 and the portion corresponding to the exhaust pipe 231. Hereinafter, the present embodiment will be described by way of an example in which the pipe heater 100 is provided at the portion corresponding to the supply pipe 10. However, configurations of the pipe heaters 100 provided at the portion corresponding to the downstream side of the valve 36 of the supply pipe 6, the portion corresponding to the downstream side of the valve 35 of the supply pipe 11, the portion corresponding to the downstream side of the valve 39 of the supply pipe 40 and the portion corresponding to the exhaust pipe 231 are substantially the same as that of the pipe heater 100 provided at the portion corresponding to the supply pipe 10.

The supply pipe 10 is configured as a pipe of a cylindrical shape through which the process gas (which is the fluid) passes. For example, the supply pipe 10 is made of a metal material such as steel. In addition, the supply pipe 10 is constituted by a plurality of pipes connected continuously in a longitudinal direction.

The pipe heater 100 is constructed by packaging a resistance heating element in an insulating material. The pipe heater 100 may be of a sheet shape. For example, it is possible to use the pipe heater 100 fitting a shape of the pipes. In addition, for example, the pipe heater 100 may be divided in the longitudinal direction, and may be installed for each pipe.

The pipe heater 100 is provided outside the supply pipe 10 via a phase change material (hereinafter, abbreviated as “PCM”) 401 which is a latent heat accumulator (latent heat accumulating material). That is, the PCM 401 is provided so as to cover an outside (outer portion) of the supply pipe 10, and the pipe heater 100 is wrapped around the supply pipe 10 of a cylindrical shape via the PCM 401. Thereby, the pipe heater 100 is configured to heat an inside (inner portion) of the supply pipe 10 while blocking the heat radiation to the outside of the supply pipe 10.

In the present specification, the PCM 401 is a heat accumulator (heat accumulating material) that uses the latent heat, and undergoes a phase change (also referred to as a “phase transition”). The PCM 401 may also be referred to as the “latent heat accumulating material”, a “latent heat material” or the “heat accumulator”. The PCM 401 undergoes the phase change, stores the heat as the phase change progresses, and maintains a constant temperature during the phase change such that its temperature remains unchanged. The term “phase change” refers to a change in a phase which is a state of a substance such as solid and liquid. The phase change is not limited to those affect atoms or molecules, and may include changes from metal to an insulator or phase changes of electrons.

The PCM 401 is provided (arranged) to cover the supply pipe 10 and is disposed outside the supply pipe 10. The PCM 401 is selected in accordance with a type of the process gas flowing through the supply pipe 10, the temperature at which the supply pipe 10 is to be maintained and a structure of the supply pipe 10. By appropriately selecting the PCM 401 corresponding to process conditions, it is possible to uniformly heat the process gas flowing through the supply pipe 10, and it is also possible to introduce (supply) the process gas flowing through the supply pipe 10 into the process chamber 201 without undergoing a phase change.

Specifically, a phase change temperature of the PCM 401 is set to be equal to or higher than a vaporization temperature of the process gas (which is a fluid in a gaseous state flowing through the supply pipe 10). Thereby, since a temperature (inner temperature) of the supply pipe 10 to be heated can be increased to a temperature equal to or higher than the vaporization temperature of the process gas, it is possible to introduce the process gas (which flows through the supply pipe 10) into the process chamber 201 at a temperature at which the process gas is not re-liquefied or re-solidified and without undergoing the phase change.

In addition, the pipe heater 100 is arranged (disposed) such that at least a part of the pipe heater 100 is in contact with the PCM 401, and is disposed outside the supply pipe 10. Preferably, the pipe heater 100 is configured such that a plurality of contact points between the pipe heater 100 and the PCM 401 are provided. In addition, the pipe heater 100 may be configured such that a plurality of combinations of the pipe heater 100 and the PCM 401 are provided.

In a manner described above, it is possible to efficiently heat the PCM 401. Then, by adjusting the phase change temperature of the PCM 401 according to respective locations where the pipe heaters 100 are disposed, it is possible to adjust the temperature in accordance with the location of the pipe.

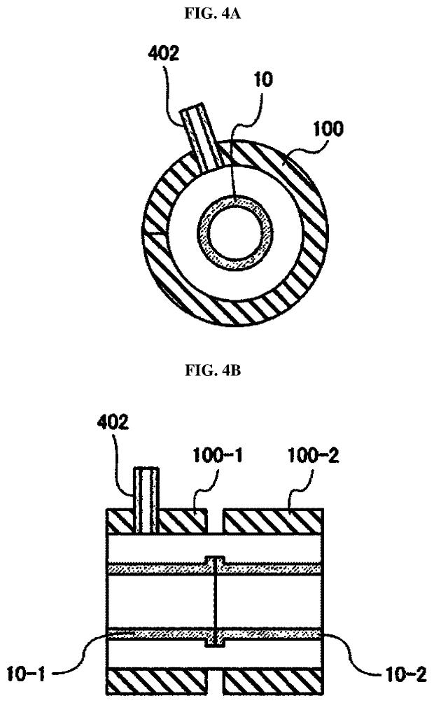

Specifically, as shown in FIGS. 4A and 4B, for example, the pipe heater 100 is wrapped around the outside of the supply pipe 10 by forming a space between the supply pipe 10 and the pipe heater 100. Then, the PCM 401 is used (provided) by filling the space between the supply pipe 10 and the pipe heater 100 via an insertion port 402 (which is provided at the pipe heater 100) connecting a front surface and a back surface of the pipe heater 100. The PCM 401 is filled in a liquid state while being pressurized and heated to a temperature equal to or higher than a melting point of the PCM 401.

In a manner described above, the pipe heater 100 is used by being wrapped around the supply pipe 10 with the PCM 401 interposed therebetween. In other words, the pipe heater 100 is used by covering a periphery of the supply pipe 10 with the PCM 401 interposed therebetween by attaching the PCM 401 to the supply pipe 10 in close contact.

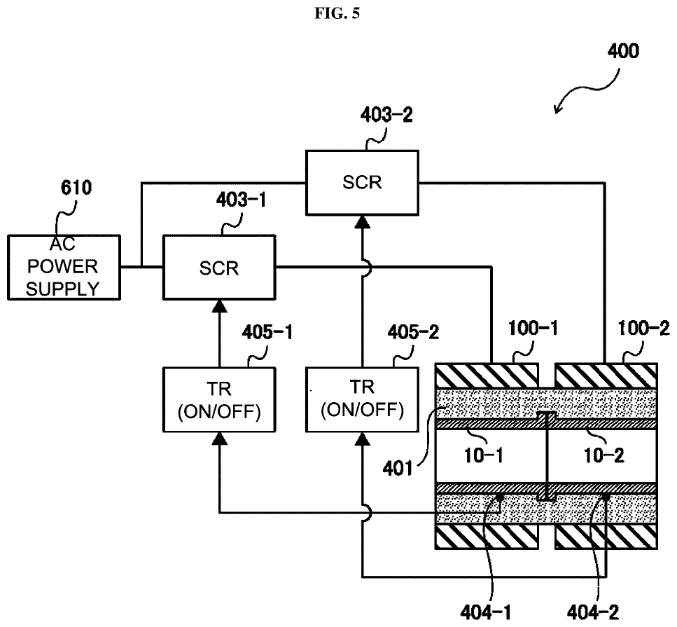

FIG. 5 is a block diagram schematically illustrating the pipe heating system 400 used in the substrate processing apparatus 1 mentioned above. Hereinafter, heating operations of supply pipes 10-1 and 10-2 constituting the supply pipe 10 will be described as an example.

The supply pipes 10-1 and 10-2 are connected continuously in the longitudinal direction. Pipe heaters 100-1 and 100-2 are provided around the supply pipes 10-1 and 10-2, respectively, via the PCM 401. Thyristors (Silicon Controlled Rectifiers, hereafter abbreviated as SCRs) 403-1 and 403-2 are connected to the pipe heaters 100-1 and 100-2, respectively. The SCRs 403-1 and 403-2 serve as power supplies (which are power supply structures) configured to supply the electric power to the pipe heaters 100-1 and 100-2, respectively. An AC power supply 610 serving as an alternating current power source is connected to the SCRs 403-1 and 403-2. Hereinafter, the SCRs 403-1 and 403-2 may also be collectively referred to as an “SCR 403”.

The AC power supply 610 supplies the electric power at a predetermined effective voltage, for example, 100V. The SCRs 403-1 and 403-2 are respectively inserted in series into a circuit including the AC power supply 610 and the pipe heater 100-1 and a circuit including the AC power supply 610 and the pipe heater 100-2. The AC power supply 610 supplies the electric power to each of the pipe heaters 100-1 and 100-2 via the SCRs 403-1 and 403-2. The pipe heaters 100-1 and 100-2 are electrically connected in parallel to the AC power supply 610.

Thermocouples 404-1 and 404-2 serving as sensors are provided inside the PCM 401 and outside the supply pipes 10-1 and 10-2, respectively. In other words, the thermocouple 404-1 is provided between the supply pipe 10-1 and the PCM 401, and the thermocouple 404-2 is provided between the supply pipe 10-2 and the PCM 401. The thermocouples 404-1 and 404-2 are configured to detect a temperature of the PCM 401 inside the pipe heaters 100-1 and 100-2 corresponding thereto, respectively. Hereinafter, the thermocouples 404-1 and 404-2 may also be collectively referred to as a “thermocouple 404”.

The thermocouples 404-1 and 404-2 are connected to temperature regulators (temperature adjusters) 405-1 and 405-2 serving as switches (which are switching structures), respectively. Hereinafter, the temperature regulator (“TR” shown in FIG. 5) 405-1 and the temperature regulator (“TR” shown in FIG. 5) 405-2 may also be collectively referred to as a “temperature regulator 405”.

The temperature regulators 405-1 and 405-2 are connected to the SCRs 403-1 and 403-2, respectively.

That is, a plurality of supply pipes (that is, N supply pipes, N is an integer of 2 or more) are provided as the supply pipe 10. Hereinafter, the supply pipes serving as the supply pipe 10 may also be referred to as “supply pipes 10”. Each of the supply pipes 10 is provided with the pipe heater 100. That is, a plurality of pipe heaters (that is, N pipe heaters) are provided as the pipe heater 100. Hereinafter, the pipe heaters serving as the pipe heaters 100 may also be referred to as “pipe heaters 100”. Each of the N pipe heaters 100 is provided with the SCR 403, the thermocouple 404 and the temperature regulator 405. That is, a plurality of SCRs (that is, N SCRs) are provided as the SCR 403, a plurality of thermocouples (that is, N thermocouples) are provided as the thermocouple 404, and a plurality of temperature regulators (that is, N temperature regulators) are provided as the temperature regulator 405. Hereinafter, the plurality of SCRs serving as the SCR 403, the plurality of thermocouples serving as the thermocouple 404 and the plurality of temperature regulators serving as the temperature regulator 405 may also be referred to as “SCRs 403”, “thermocouples 404” and “temperature regulators 405”, respectively.

Each of the temperature regulators 405 is configured to transmit (send) a control pulse signal to the SCR 403 corresponding thereto depending on an amount of the heat accumulated in the PCM 401 corresponding thereto. When the SCR 403 receives the control pulse signal, the SCR 403 switches a power supply (that is, a supply of the electric power) to the pipe heater 100 corresponding thereto to turn on or turn off. Thereby, each of the temperature regulators 405 can turn the power supply to the pipe heater 100 on or off before the temperature of the PCM 401 deviates from the phase change temperature.

That is, the controller 321 is configured to be capable of controlling the temperature regulator 405 to switch the pipe heater 100 corresponding thereto to turn on or turn off before the temperature of the PCM 401 detected by the thermocouple 404 deviates from the phase change temperature.

In other words, by using the properties of the PCM 401, it is possible to maintain a temperature of the supply pipe 10 at the phase change temperature of the PCM 401, and it is also possible to uniformly heat the supply pipe 10 by the PCM 401.

That is, to maintain the temperature of the PCM 401 at the phase change temperature, the controller 321 is configured to be capable of controlling the SCRs 403 such that the supply pipes 10 are heated by the pipe heaters 100, respectively.

Specifically, the controller 321 compares the amount of the heat accumulated in the PCM 401 at the phase change temperature with a preset lower or upper limit of the amount of the heat accumulated (that is, a first threshold value) to determine whether to turn on or turn off each of the pipe heaters 100. In the present embodiment, the first threshold value is an amount of the heat at which the PCM 401 is maintained at the phase change temperature, and allows a margin in the amount of the heat that deviates from the phase change temperature.

The amount of the heat accumulated in the PCM 401 may vary depending on a parameter such as a type of the PCM 401 and the process conditions. The first threshold value is stored in the memory 321c and/or the external memory 323, and is calculated by the CPU 321a.

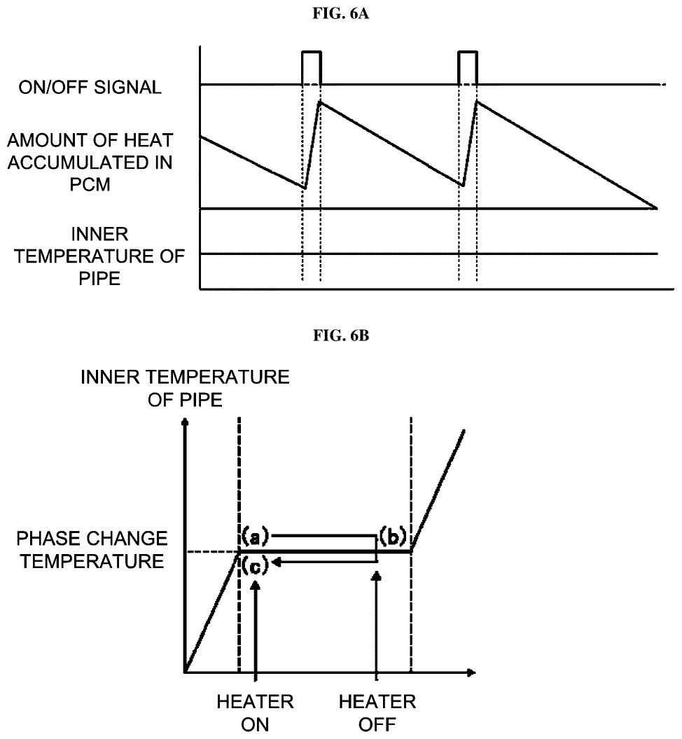

FIG. 6A is a diagram schematically illustrating a relationship among an on/off signal for the pipe heater 100, the amount of the heat accumulated in the PCM 401 and a temperature (inner temperature) of the supply pipe 10. Hereinafter, the inner temperature of the supply pipe 10 may also be referred to as an “inner temperature of the pipe” or an “inner temperature of the piping structure”.

As shown in FIG. 6A, before the amount of the heat accumulated in the PCM 401 reaches the lower limit, by a control pulse of an on signal from the temperature regulator 405, the SCR 403 starts the power supply to the pipe heater 100 corresponding thereto. Then, before the amount of the heat accumulated in the PCM 401 reaches the upper limit, by a control pulse of an off signal from the temperature regulator 405, the SCR 403 stops the power supply to the pipe heater 100 corresponding thereto. As a result, it is possible to maintain the inner temperature of the supply pipe 10 at the phase change temperature of the PCM 401.

In addition, each of the temperature regulators 405 switches the power supply to the pipe heater 100 by the SCR 403 to turn on or turn off by using the control pulse of the on signal or the control pulse of the off signal depending on a phase change temperature maintaining time (which is a time (time duration) elapsed since the PCM 401 reaches the phase change temperature). Thereby, it is possible to turn the power supply to each of the pipe heaters 100 on or off before the temperature of the PCM 401 deviates from the phase change temperature.

That is, similar to a case where the amount of the heat accumulated in the PCM 401 is used to switch the power supply to each of the pipe heaters 100 as described above, the controller 321 controls the SCR 403 corresponding thereto such that each of the supply pipes 10 is heated by each of the pipe heaters 100 and the PCM 401 is maintained at the phase change temperature.

That is, the controller 321 compares the phase change temperature maintaining time with a preset second threshold value to determine whether to turn on or turn off the pipe heater 100 corresponding thereto. In the present embodiment, the second threshold value is a time (time duration) during which the PCM 401 is maintained at the phase change temperature, and allows a margin in the time during which the temperature of the PCM 401 deviates from the phase change temperature.

The second threshold value may vary depending on a parameter such as the type of the PCM 401 and the process conditions. For example, the second threshold value is set to 5% less than the time during which the phase change temperature of the PCM 401 is actually maintained. The second threshold value is stored in the memory 321c or the external memory 323.

FIG. 6B is a diagram schematically illustrating a relationship between an on/off control for the pipe heater 100 and the temperature (inner temperature) of the supply pipe 10, that is, the inner temperature of the pipe.

As shown in FIG. 6B, after the power supply is started, the heating is started, and the temperature of the PCM 401 becomes constant (“(a)” shown in FIG. 6B). Then, when the phase change temperature maintaining time reaches the second threshold value, the SCR 403 stops the power supply to the pipe heater 100 corresponding thereto by the control pulse of the off signal from the temperature regulator 405 (“(b)” shown in FIG. 6B). Then, when the power supply is stopped and the phase change temperature maintaining time of the PCM 401 reaches the second threshold, the SCR 403 starts the power supply to the pipe heater 100 corresponding thereto by the control pulse of the on signal from the temperature regulator 405 (“(c)” shown in FIG. 6B). As a result, it is possible to maintain the inner temperature of the supply pipe 10 at the phase change temperature of the PCM 401.

In the present embodiment, while the power supply to the pipe heater 100 is turned on, the heat is absorbed by the PCM 401, the PCM 401 undergoes the phase change from a low temperature phase (for example, a solid state) to a high temperature phase (for example, a liquid state), and the temperature of the PCM 401 maintains the phase change temperature. Therefore, the temperature of the supply pipe 10 inside the PCM 401 is maintained at the phase change temperature. In contrast, while the power supply to the pipe heater 100 is turned off, the heat held by the PCM 401 is radiated mainly to the supply pipe 10 inside the PCM 401, and slightly to the pipe heater 100 outside the PCM 401. In such a state, the PCM 401 undergoes the phase change from the high temperature phase (liquid state) to the low temperature phase (solid state), and the temperature of the PCM 401 maintains the phase change temperature. Therefore, the temperature of the supply pipe 10 inside the PCM 401 is controlled (adjusted) to the phase change temperature.

As described above, the parameter such as the first threshold value (which is the lower or upper limit of the amount of the heat accumulated at which the temperature of the PCM 401 deviates from the phase change temperature) and the second threshold value (which is the time during which the PCM 401 is maintained at the phase change temperature) is stored in advance in the memory 321c or the external memory 323. By using the amount of the heat accumulated in the PCM 401 or phase change temperature maintaining time of the PCM 401, it is possible to heat the supply pipe 10 by the PCM 401 while maintaining the phase change temperature before the temperature of the PCM 401 deviates from the phase change temperature. Therefore, it is possible to uniformly heat the supply pipe 10 at a constant temperature.

### Effects According to Present Embodiment

According to the present embodiment, it is possible to obtain one or more of the following effects (a) to (c).
(a) Because the pipe can be heated by the pipe heater via the latent heat accumulator, it is possible to uniformly heat the pipe at a constant temperature.
(b) By uniformly heating the inside of the pipe, it is possible to suppress a re-liquefaction and a re-solidification of the gas flowing through the pipe, and it is also possible to prevent the gas containing particles from being supplied to the process chamber. Thereby, it is possible to suppress a deterioration of a quality of the substrate processing.

### (c) Regardless of the shape and structure of the pipe, it is possible to attach the latent heat accumulator to the pipe in close contact. Thereby, it is possible to uniformly heat the pipe.

### Second Embodiment

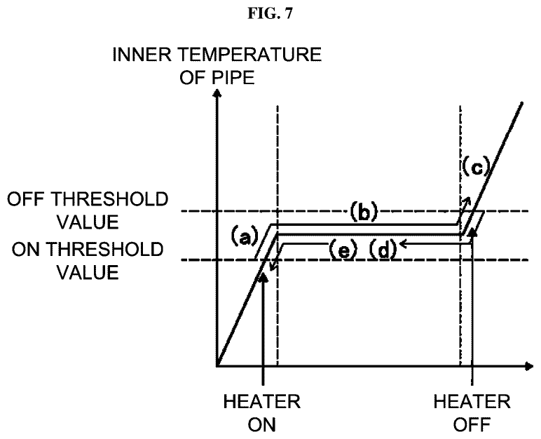

Subsequently, another example of the pipe heating system (that is, a pipe heating system according to a second embodiment of the present disclosure) will be described with reference to FIG. 7. The pipe heating system according to the present embodiment is configured similarly to that of the substrate processing apparatus 1 shown in FIG. 1. In the description of the present embodiment described below, substantially the same components as those of the first embodiment described with reference to FIG. 1 will be denoted by like reference numerals, and detailed descriptions thereof will be omitted.

The present embodiment differs from the first embodiment mentioned above in the operation of the temperature regulator 405. In the present embodiment, the temperature regulator 405 switches the power supply to the pipe heater 100 by the SCR 403 to turn on or turn off by the control pulse of the on signal or the control pulse of the off signal, depending on the temperature detected by the thermocouple 404 corresponding thereto.

The controller 321 is configured to be capable of controlling the temperature of the PCM 401 based on the temperature detected by each of the thermocouples 404. In other words, by comparing the phase change temperature of the PCM 401 with the temperatures detected by each of the thermocouples 404, in other words by matching them, each of the supply pipes 10 is heated to a constant temperature.

That is, the controller 321 is configured to be capable of controlling each of the temperature regulators 405 to switch the power supply to the pipe heater 100 corresponding thereto to turn on or turn off when the temperature detected by each of the thermocouples 404 deviates from the phase change temperature of the PCM 401. Thereby, it is possible to adjust the temperature of the PCM 401 to the phase change temperature.

Specifically, the temperature regulator 405 compares the temperature detected by the thermocouple 404 corresponding thereto with a set temperature. In addition, the temperature regulator 405 is configured to control the power supply to the pipe heater 100 to be turned on or off such that the temperature detected by the thermocouple 404 approaches the phase change temperature of the PCM 401. In such an operation, as the set temperature, an off threshold value and an on threshold value may be used. The off threshold value is set such that the power supply to the pipe heater 100 is turned off when the temperature of the PCM 401 deviates from the phase change temperature, and the on threshold value is set such that the power supply to the pipe heater 100 is turned on when the temperature of the PCM 401 is lower than the phase change temperature.

As shown in FIG. 7, while the power supply to the pipe heater 100 is turned off, the heat held by the PCM 401 is radiated mainly to the supply pipe 10 inside the PCM 401, and slightly to the pipe heater 100 outside the PCM 401. In such a state, the PCM 401 undergoes the phase change from the high temperature phase (liquid state) to the low temperature phase (solid state). When the time during which the power supply to the pipe heater 100 is turned off continues, an entirety of the PCM 401 enters into the low temperature phase, the heat accumulated in the PCM 401 is dissipated, the temperature of the PCM 401 deviates from the phase change temperature and starts decreasing while remaining in the low temperature phase (“(e)” shown in FIG. 7). In addition, when the temperature of the PCM 401 falls below the on threshold value of the pipe heater 100, the SCR 403 starts the power supply to the pipe heater 100 corresponding thereto by the control pulse of the on signal of the temperature regulator 405. That is, the power supply to the pipe heater 100 is turned on, and the heating of the pipe is started (“(a)” in FIG. 7). Then, while the power supply to the pipe heater 100 is turned on, the heat is absorbed by the PCM 401, and the PCM 401 undergoes the phase change from the low temperature phase (solid state) to the high temperature phase (liquid state), during which the temperature of the PCM 401 maintains the phase change temperature (“(b)” shown in FIG. 7). In addition, when the time during which the power supply to the pipe heater 100 is turned on continues, the entirety of the PCM 401 enters into the high temperature phase, and the heat cannot be accumulated in the PCM 401 any further. Then, the temperature of the PCM 401 deviates from the phase change temperature and starts increasing while remaining in the high temperature phase (“(c)” in FIG. 7). For example, when the temperature of the PCM 401 exceeds the off threshold value of the pipe heater 100, the SCR 403 stops the power supply to the pipe heater 100 corresponding thereto by the control pulse of the off signal of the temperature regulator 405. When the power supply to the pipe heater 100 is stopped, the PCM 401 releases the heat and undergoes the phase change from the high temperature phase (liquid state) to the low temperature phase (solid state). During such a phase change, the temperature of the PCM 401 remains at the phase change temperature (“(d)” shown in FIG. 7). As a result, it is possible to maintain the inner temperature of the supply pipe 10 at the phase change temperature of the PCM 401.

According to the present embodiment, it is possible to obtain substantially the same effects as in the first embodiment mentioned above.

For example, a detector configured to detect an occurrence of the phase change in the PCM 401 may be further provided. By detecting the occurrence of the phase change in the PCM 401, the controller 321 may control each of the temperature regulators 405 to switch each of the pipe heaters 100 to turn on or turn off before the temperature of the PCM 401 deviates from the phase change temperature. By detecting the phase change in the latent heat accumulator in a manner described above and by switching the pipe heater 100 corresponding thereto to turn on or turn off, the supply pipe 10 is heated by the PCM 401 using the properties of the PCM 401 without the temperature of the PCM 401 deviating from the phase change temperature. Therefore, it is possible to uniformly heat the supply pipe 10 at a constant temperature (for example, the phase change temperature).

### Third Embodiment

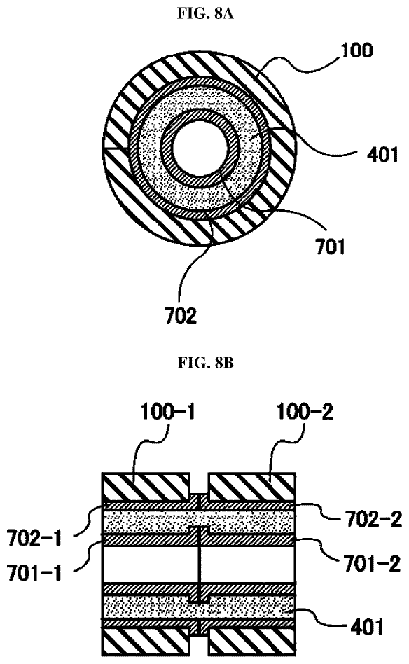

Subsequently, still another example of the pipe heating system (that is, a pipe heating system according to a third embodiment of the present disclosure) will be described with reference to FIGS. 8A and 8B. The pipe heating system according to the present embodiment is configured similarly to that of the substrate processing apparatus 1 shown in FIG. 1.

The pipe heating system according to the present embodiment uses a double pipe structure constituted by a first pipe 701 and a second pipe 702 instead of the supply pipe 10.

The fluid such as the first process gas flows inside the first pipe 701. The second pipe 702 is provided outside the first pipe 701 via the PCM 401. The pipe heater 100 is provided outside the second pipe 702.

That is, an inside of the second pipe 702 is filled with the PCM 401, and the PCM 401 is arranged between the first pipe 701 and the second pipe 702.

Pipes 701-1 and 701-2 constituting the first pipe 701 are connected continuously in the longitudinal direction. Hereinafter, the pipes 701-1 and 701-2 may also be referred to as “first pipes 701-1 and 701-2”. Pipes 702-1 and 702-2 constituting the second pipe 702 are provided around the first pipes 701-1 and 701-2, respectively, via the PCM 401. Hereinafter, the pipes 702-1 and 702-2 may also be referred to as “second pipes 702-1 and 702-2”. In addition, the pipe heaters 100-1 and 100-2 are provided outside the second pipes 702-1 and 702-2, respectively. In other words, a plurality of pipe heaters 100-1 and 100-2 are provided in the longitudinal direction, and the pipe heaters 100-1 and 100-2 are provided so as to cover the second pipes 702-1 and 702-2, respectively. That is, the pipe heater 100 is provided separately for each of the second pipes 702-1 and 702-2. In other words, the pipe heaters 100 are provided separately for the second pipes 702-1 and 702-2 constituting the second pipe 702, respectively.

The SCRs 403-1 and 403-2 are connected to the pipe heaters 100-1 and 100-2, respectively. The SCRs 403-1 and 403-2 are configured to supply the electric power to the pipe heaters 100-1 and 100-2, respectively.

To maintain the temperature of the PCM 401 at the phase change temperature, the controller 321 is configured to be capable of controlling the SCRs 403-1 and 403-2 such that the first pipes 701-1 and 701-2 and the second pipes 702-1 and 702-2 are heated by the pipe heaters 100-1 and 100-2.

The AC power supply 610 is connected to the SCRs 403-1 and 403-2. The AC power supply 610 supplies the electric power respectively to the pipe heaters 100-1 and 100-2 via the SCRs 403-1 and 403-2.

The thermocouples 404-1 and 404-2 are provided inside the PCM 401 and outside the first pipes 701-1 and 701-2, respectively. In other words, the thermocouple 404-1 is provided between the first pipe 701-1 and the PCM 401, and the thermocouple 404-2 is provided between the first pipe 701-2 and the PCM 401. The thermocouples 404-1 and 404-2 are configured to detect the temperature of the PCM 401 inside the pipe heaters 100-1 and 100-2 corresponding thereto, respectively.

The thermocouples 404-1 and 404-2 are connected to the temperature regulators 405-1 and 405-2 serving as switches (which are switching structures), respectively.

The temperature regulators 405-1 and 405-2 are connected to the SCRs 403-1 and 403-2, respectively.

According to the present embodiment, it is possible to obtain substantially the same effects as in the first embodiment mentioned above. In other words, similar to the pipe heating system according to the first embodiment mentioned above, by using the properties of the PCM 401, it is possible to maintain the temperature of the supply pipe 10 at the phase change temperature of the PCM 401, and it is also possible to uniformly heat the supply pipe 10 by the PCM 401.

While the technique of the present disclosure is described in detail by way of the embodiments mentioned above, the technique of the present disclosure is not limited thereto and may be modified in various ways without departing from the scope thereof.

For example, the embodiments mentioned above are described by way of an example in which the pipe heaters 100 are provided at the portion corresponding to the downstream side of the valve 36 of the supply pipe 6, the portion corresponding to the supply pipe 10, the portion corresponding to the downstream side of the valve 35 of the supply pipe 11, the portion corresponding to the downstream side of the valve 39 of the supply pipe 40 and the portion corresponding to the exhaust pipe 231. However, the technique of the present disclosure is not limited thereto. For example, the technique of the present disclosure may be applied to a pipe other than the pipes mentioned above, and may also be applied to at least one among the portion corresponding to the downstream side of the valve 36 of the supply pipe 6, the portion corresponding to the supply pipe 10, the portion corresponding to the downstream side of the valve 35 of the supply pipe 11, the portion corresponding to the downstream side of the valve 39 of the supply pipe 40 and the portion corresponding to the exhaust pipe 231.

For example, the embodiments mentioned above are described by way of an example in which the pipe heater 100 is provided for each pipe. However, the technique of the present disclosure is not limited thereto. For example, the technique of the present disclosure may be applied when the pipe heater 100 alone is provided for an entirety of the pipes.

For example, the embodiments mentioned above are described by way of an example in which the pipe heater 100 is controlled to be turned on and turned off. However, the technique of the present disclosure is not limited thereto. For example, the technique of the present disclosure may be applied when a feed-back control, a feed-forward control or a PID control is used.

For example, a power regulator or the like may be used instead of the SCR 403, and the temperature regulator 405 may be configured to continuously and variably control an amount of the electric conduction to the pipe heater 100 such that the temperature detected by the thermocouple 404 is set to be close to the phase change temperature of the PCM 401.

As the PCM 401, for example, an alloy containing tin (Sn) or vanadium dioxide (VO₂ type) may be used. As the alloy containing tin, for example, a substance obtained by changing a composition ratio of an element such as indium (In), silver (Ag) and copper (Cu) in the alloy containing tin may be used.

For example, the embodiments mentioned above are described by way of an example in which the film forming process is performed as the substrate processing performed by the substrate processing apparatus. However, the technique of the present disclosure is not limited thereto. For example, the technique of the present disclosure may be applied not only to a semiconductor manufacturing apparatus but also to an apparatus configured to processes a glass substrate such as an LCD device. In addition, for example, the film forming process may include a process such as a CVD (chemical vapor deposition) process, a PVD (physical vapor deposition) process, a process of forming an oxide film, a nitride film or both of the oxide film and the nitride film, and a process of forming a film containing a metal. In addition, the technique of the present disclosure may be similarly applied to other processes such as an annealing process, an oxidation process, a nitriding process and a diffusion process.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of simultaneously processing one or several substrates is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process procedures and the process conditions of each process using the substrate processing apparatuses exemplified above may be substantially the same as those of the embodiments mentioned above. Even in such a case, it is possible to obtain substantially the same effects as in the embodiments mentioned above.

For example, the embodiments mentioned above are described by way of an example in which the pipe used in the substrate processing apparatus is heated as an object to be heated. However, the technique of the present disclosure is not limited thereto. For example, the technique of the present disclosure may be preferably applied when another pipe is heated.

While the technique of the present disclosure is described in detail by way of various typical embodiments mentioned above, the technique of the present disclosure is not limited thereto. For example, the technique of the present disclosure may be applied even when the embodiments mentioned above are appropriately combined.

As described above, according to some embodiments of the present disclosure, it is possible to uniformly heat the piping structure.

What is claimed is:

1. A pipe heating system comprising:
a latent heat accumulator arranged outside a pipe through which a fluid flows;
a heater arranged outside the latent heat accumulator;
a power supply configured to supply an electric power to the heater; and
a controller configured to be capable of controlling the power supply such that the heater heats the pipe to maintain a temperature of the latent heat accumulator at a phase change temperature.

2. The pipe heating system of claim 1, wherein:
the latent heat accumulator is provided to cover the pipe, and
the heater is connected to the latent heat accumulator such that at least a part of the heater is in contact with the latent heat accumulator.

3. The pipe heating system of claim 2, wherein the heater is configured such that a plurality of contact points between the heater and the latent heat accumulator are provided.

4. The pipe heating system of claim 2, wherein the heater is configured such that a plurality of combinations of the heater and the latent heat accumulator are provided.

5. The pipe heating system of claim 1, further comprising:
a sensor configured to detect the temperature of the latent heat accumulator,
wherein the controller is further configured to be capable of controlling the temperature of the latent heat accumulator based on a temperature detected by the sensor.

6. The pipe heating system of claim 5, further comprising:
a switching structure configured to switch the heater to turn on or turn off,
wherein the controller is further configured to be capable of controlling the switching structure to switch the heater to turn on or turn off before the temperature detected by the sensor deviates from the phase change temperature.

7. The pipe heating system of claim 5, further comprising:
a switching structure configured to switch the heater to turn on or turn off,
wherein the controller is further configured to be capable of controlling the switching structure to switch the heater to turn on or turn off when the temperature detected by the sensor deviates from the phase change temperature.

8. The pipe heating system of claim 1, wherein the controller is further configured to compare an amount of a heat accumulated in the latent heat accumulator at the phase change temperature with a predetermined first threshold value to determine whether to switch the heater to turn on or turn off.

9. The pipe heating system of claim 8, wherein the first threshold value is an amount of
the heat at which the latent heat accumulator is maintained at the phase change temperature.

10. The pipe heating system of claim 1, wherein:
the controller is further configured to compare a phase change temperature maintaining time with a predetermined second threshold value to determine whether to switch the heater to turn on or turn off, and
the phase change temperature maintaining time is a time duration elapsed since the latent heat accumulator reaches at the phase change temperature.

11. The pipe heating system of claim 10, wherein the second threshold value is a time duration during which the latent heat accumulator is maintained at the phase change temperature.

12. The pipe heating system of claim 1, further comprising:
a switching structure configured to switch the heater to turn on or turn off,
wherein the controller is further configured to be capable of controlling the switching structure to switch the heater to turn on or turn off before the temperature of the latent heat accumulator deviates from the phase change temperature.

13. The pipe heating system of claim 1, wherein the phase change temperature of the latent heat accumulator is set to be equal to or higher than a vaporization temperature of the fluid in a gaseous state flowing through the pipe.

14. The pipe heating system of claim 1, wherein the latent heat accumulator is selected in accordance with a type of the fluid flowing through the pipe, a temperature at which the pipe is to be maintained and a structure of the pipe.

15. The pipe heating system of claim 1, further comprising:
a first pipe through which the fluid flows; and
a second pipe provided outside the first pipe,
wherein the latent heat accumulator is disposed between the first pipe and the second pipe.

16. The pipe heating system of claim 15, wherein the latent heat accumulator is filled between the first pipe and the second pipe.

17. The pipe heating system of claim 15, further comprising:
one or more heaters,
wherein the heater and the one or more heaters are provided separately for a plurality of pipes constituting the second pipe.

18. A substrate processing apparatus comprising:
a pipe through which a process gas is supplied into a process chamber where a substrate is processed;
a latent heat accumulator arranged outside the pipe;
a heater arranged outside the latent heat accumulator and configured to heat the pipe;
a power supply configured to supply an electric power to the heater; and
a controller configured to be capable of controlling the power supply such that the heater heats the pipe to maintain a temperature of the latent heat accumulator at a phase change temperature.

19. A method of manufacturing a semiconductor device, comprising:
processing a substrate arranged in a process chamber by supplying a process gas into the process chamber while heating the process gas by heating a pipe through which the process gas flows by a heater,
wherein the heater is arranged outside a latent heat accumulator, the latent heat accumulator is arranged outside the pipe, and the heater heats the pipe by supplying an electric power to the heater to maintain a temperature of the latent heat accumulator at a phase change temperature.
